(19) United States
(12) Patent Application Publication
(10) Pub. No.: US 2008/0014510 A1
(43) Pub. Date: Jan. 17, 2008

(54) PHOTOMASK DESIGNING APPARATUS, PHOTOMASK, PHOTOMASK DESIGNING METHOD, PHOTOMASK DESIGNING PROGRAM AND COMPUTER-READABLE STORAGE MEDIUM ON WHICH THE PHOTOMASK DESIGNING PROGRAM IS STORED

(75) Inventors: Tadahito FUJISAWA, Yokkaichi (JP); Takeshi Ito, Yokkaichi (JP); Yoshihiro Yanai, Yokkaichi (JP); Atsushi Maesono, Yokohama (JP); Kazuya Fukuhara, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/777,481

(22) Filed: Jul. 13, 2007

(30) Foreign Application Priority Data
Jul. 13, 2006 (JP) 2006-192867

(51) Int. Cl. G03C 5/00; G06F 17/50; G03F 1/00

(52) U.S. Cl. 430/5; 430/394; 716/21

(57) ABSTRACT

A photomask designing apparatus designs a photomask provided with a light transmission region through which exposure light with a predetermined wavelength transmits, a semi-transmission region having an optical characteristic of 180-degree phase shift and a light shielding region shielding exposure light. The semi-transmission region has a width set so as to be larger as a distance from the semi-transmission region to the light shielding region becomes short with respect to a region in which the semi-transmission region, the light transmission region and the light shielding region are sequentially formed outward from an exposure light passing region side. The width of the semi-transmission region is set so as to be smaller as the distance becomes long.

### CROSS-REFERENCE TO RELATED APPLICATIONS

This application is based on and claims the benefit of priority from the prior Japanese Patent Application No. 2006-192867, filed on Jul. 13, 2006, the entire contents of which are incorporated herein by reference.

### BACKGROUND OF THE INVENTION

1. Field of the Invention

The present invention relates to a photomask designing apparatus for forming a mask pattern, a photomask, a photomask designing method, a photomask designing program and a computer readable storage medium on which the photomask designing program is stored.

2. Description of the Related Art

Photomasks are generally used to form mask patterns of various types of semiconductor devices. It is known that linewidth of a photomask varies for many factors. Various techniques for suppressing dimensional variations have been proposed in order that a desired mask pattern may be formed. JP-2001-188337A discloses a technique for reducing dimensional differences between dense and isolated patterns which are mixed in a semiconductor mask by interposing a dummy pattern on a transparent substrate.

JP-2003-100624A discloses a technique in which a photolithography process is carried out and linewidths of photoresist pattern in light shielding region and light transmission regions are compared with each other. Lens flare is quantified by the results of comparison, so that a region which is to constitute a wafer and to be affected by the lens flare is measured. Furthermore, an open/close operation ratio is measured in a region which is affected by the lens flare depending upon an amount of lens flare. The linewidth of the mask pattern is corrected by the measured open/close operation ratio so that a uniform pattern is obtained on the wafer.

Furthermore, JP-2005-203637A discloses a lithography process evaluation system comprising an exposure system performing multiple exposure of a periodic pattern region and a window pattern on the same region of a wafer, a linewidth measuring section measuring dimensional variations in a linewidth of a projected image in the periodic pattern region on the basis of a position of image obtained by projecting the window pattern, and a coverage ratio dependency evaluation section evaluating a dimensional variation factor depending upon the coverage of the mask, so that the dimensional variation factor in the lithography process can accurately be evaluated.

JP-2005-338267A discloses a mask pattern correction method comprising the steps of measuring distribution of projected light intensity, computing a distribution function of local flare produced depending upon a mask pattern coverage of a monitor mask pattern based on a first ratio of illumination light intensity of the monitor mask pattern to a first projection light intensity on a semiconductor substrate computed from the monitor mask pattern, and the projected light intensity distribution, dividing a design mask pattern of the object photomask into a plurality of unit regions, and computing a second ratio of the illumination light intensity in each of the plurality of unit regions to second projected light intensity on the semiconductor substrate computed from the design mask pattern, and based on the distribution function. Thus, dimensional variations are obtained and the mask pattern is corrected, whereby a desired photomask pattern can be obtained.

For example, a memory cell region of a NAND flash memory has recently required refinement. Accordingly, an exposure process to be applied needs to be approximated to the resolution limit of exposure equipment, that is, a finer and denser pattern than the conventional one needs to be formed in the memory cell region. A phase shift mask needs to be used in order that such a fine pattern as mentioned above may be exposed to light. The phase shift mask is provided with a light transmission region through which exposure light with a predetermined wavelength passes, a semi-transmission (half-tone) region shifting phase 180 degrees relative to the exposed light and a light-shielded region. However, the inventors found that dimensional distortion resulted from some influence even if a resolution was obtained at the limit of the number of apertures (NA) and a pattern was then exposed to light thereby to carry out such a simple correction as described above. As a result, dimensional variations cannot be suppressed sufficiently.

### BRIEF SUMMARY OF THE INVENTION

Therefore, an object of the present invention is to provide a photomask designing apparatus, photomask designing method, photomask designing program all of which can form a desired fine pattern with a reduced amount of dimensional variation, a storage medium on which the photomask designing program is stored, and the photomask.

The present invention provides a photomask designing apparatus designing a photomask which is provided with a light transmission region through which exposure light with a predetermined wavelength transmits, a semi-transmission region having an optical characteristic of 180-degree phase shift and a light shielding region shielding exposure light, wherein the semi-transmission region has a width set so as to be larger as a distance from the semi-transmission region to the light shielding region becomes short with respect to a region in which the semi-transmission region, the light transmission region and the light shielding region are sequentially provided outward from an exposure light passing region side, and the width of the semi-transmission region is set so as to be smaller as the distance becomes long.

The invention also provides a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising setting the width of the semi-transmission region so that the width of the semi-transmission region is larger as a distance from the semi-transmission region to the light shielding region becomes short with respect to a region in which the semi-transmission region, the light transmission region and the light shielding region are sequentially provided outward from an exposure light passing region side, and setting the width of the semi-transmission region so that the width of the semi-transmission region is smaller as the distance becomes long.

The invention further provides a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising setting the width of the semi-transmission region so that the width of the semi-transmission region is larger as a distance from the semi-transmission region to the light shielding region becomes short with respect to a region in which the semi-transmission region, the light transmission region and the light shielding region are sequentially provided outward from an exposure light passing region side, and setting the width of the semi-transmission region so that the width of the semi-transmission region is smaller as the distance becomes long.

The invention further provides a photomask designing apparatus designing a photomask which is provided with a light transmission region through which exposure light with a predetermined wavelength transmits, a semi-transmission region having an optical characteristic of 180-degree phase shift and a light shielding region, wherein the light transmission region has a width set so as to be larger as a distance from the light transmission region to the light shielding region becomes short with respect to a region in which the light transmission region, the semi-transmission region and the light shielding region are sequentially provided outward from an exposure light passing region side, and the width of the light transmission region is set so as to be smaller as the distance becomes long.

The invention still further provides a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising setting the width of the semi-transmission region so that the width of the semi-transmission region is larger as a distance from the light transmission region to the light shielding region becomes short with respect to a region in which the light transmission region, the semi-transmission region and the light shielding region are sequentially provided outward from an exposure light passing region side, and setting the width of the semi-transmission region so that the width of the light transmission region is smaller as the distance becomes long.

### BRIEF DESCRIPTION OF THE DRAWINGS

Other objects, features and advantages of the present invention will become clear upon reviewing the following description of one embodiment with reference to the accompanying drawings, in which:

FIG. 1A illustrates a whole region resist pattern in a first embodiment in accordance with the present invention;

FIG. 1B illustrates a photomask pattern in the case where a memory cell region is exposed to light;

FIG. 1C illustrates a photomask pattern in the case where a peripheral circuit region is exposed to light;

FIG. 1D illustrates a photomask pattern in the case where a memory cell region is exposed to light;

FIG. 2 is a schematic block diagram showing an electrical arrangement of a semiconductor design and fabrication management system;

FIG. 3A illustrates the construction of an exposure apparatus;

FIG. 3B is a plan view of illumination conditions in the case where a memory cell region is exposed to light;

FIG. 3C is a plan view of illumination conditions in the case where the peripheral circuit region is exposed to light;

FIG. 3D is a plan view of illumination conditions in the case where a memory cell region is exposed to light;

FIG. 4A shows the result of measurement of resist width (No. 1);

FIG. 4B shows the result of measurement of resist width (No. 2);

FIG. 4C shows the definition of a distance;

FIG. 5A schematically shows distance dependency of an amount of dimensional correction; and

FIG. 5B schematically shows distance dependency of an amount of received light.

### DETAILED DESCRIPTION OF THE INVENTION

One embodiment of the present invention will be described with reference to the accompanying drawings. In the embodiment, the invention is applied to a photomask designing apparatus for forming a pattern including a fine line-and-space pattern having a large peripheral resist-removed region around which a large resist-applied region remains.

Refined semiconductor device patterns have necessitated a technique for accurately controlling linewidth of a pattern formed on a semiconductor substrate by a lithography process. An optical proximity effect (OPE) is one of causes of dimensional variations of a resist formed on a semiconductor substrate although a mask pattern has a uniform dimension. OPE shows a phenomenon that dimensions of a resist vary after exposure depending upon the density of a pattern formed around another pattern. OPE is peculiar in a pattern with dimensions which are approximate to a resolution limit. OPE can generally be suppressed by an optical proximity correction (OPC) in which dimensional variations are estimated from lithography simulation which takes into consideration a configuration of pattern with a periphery of about several μm wide. Dimensions of the mask pattern are corrected based on the estimated value.

Furthermore, experiments and simulation were carried out to obtain the relationship between dimensional variations of the target pattern and the state of peripheral pattern regarding the similar dimensional variations (called “process proximity effect (PPE)) caused in a developing process in addition to exposure, so that each process is improved such that dimensional variations are suppressed or mask dimensions are changed for the purpose of dimensional correction of the resist. Still furthermore, another problem relates to influences of the covering state of mask in a larger range (100 μm to 1000 μm) than OPC.

For example, a memory cell array provided with a number of memory cells needs to be formed in a memory cell region of a NAND flash memory. In this case, patterns of a number of memory cells need to be formed so as to have a uniform linewidth. However, overcoming this problem has become difficult. In particular, this has become a more important problem to be overcome as refinement of pattern to be formed has advanced. A memory cell array comprises a plurality of memory cells connected into a NAND type.

For example, when a wide opening exists near one pattern, the linewidth of the pattern varies. This phenomenon is referred to as “coverage dependency” which is a dimensional variation depending upon a local coverage of mask. The phenomenon is considered to result from flare generated in an exposure apparatus, acid evaporating from photoresist during post exposure bake (PEB), re-adherence of the acid onto the semiconductor substrate, bias of developer density during development (micro-loading), etc.

The inventors repeatedly studied the semiconductor substrate exposing process, PEB, problems of developing process, influences of dimensional variations of mask pattern and the like. The inventors further studied dimensional variations in the linewidth with application of the techniques disclosed in JP-2001-188337A, JP-2003-100624A, JP-2005-203637A and JP-2005-338267A. However, the inventors found that the problem of dimensional variations could not be overcome in the case of a region to which exposure approximate to the resolution limit was necessitated to be applied, such as a memory cell region of a NAND flash memory, even if the techniques of the aforementioned references were combined together and the process was carried out with a resolution obtained at the limit of the number of apertures (NA).

Furthermore, a peripheral circuit region is provided so as to be adjacent to the memory cell region. Problems arise also when double (multiple) exposure is carried out for these regions. The multiple exposure forms an intensity distribution by image synthesis using a plurality of mask patterns, and such an intensity distribution cannot be realized by a single time of exposure process. A mask pattern and illumination condition can be optimized in each exposure process with advantage.

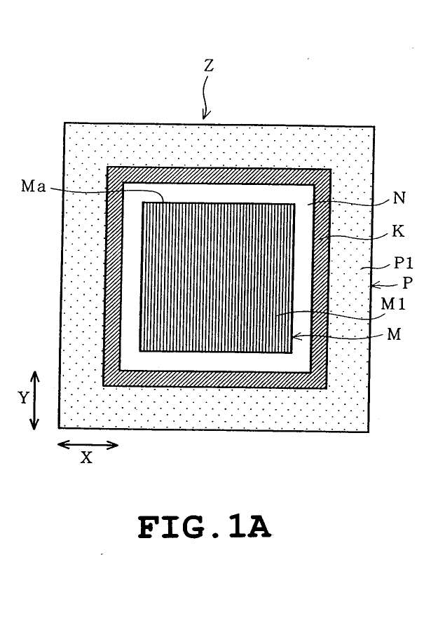

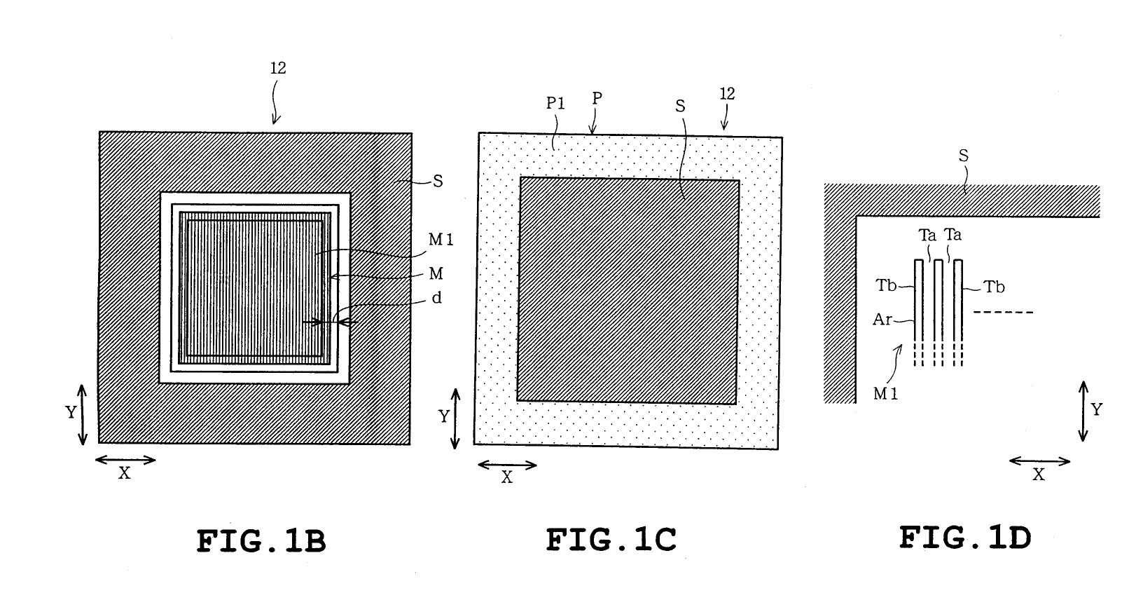

FIG. 1A is a plan view showing a region where a memory cell region and peripheral circuit region of a NAND flash memory are to be configured and an example of resist pattern. A memory cell region M is provided substantially in a central part of the whole region Z of the pattern. A peripheral circuit pattern region P is provided around the memory cell region M. A drive circuit (not shown) for driving a memory cell array (not shown) is formed in the memory cell region M. Various drive transistors and the like are composed in the region M. Accordingly, the memory cell region M necessitates a refining process, whereas the design rule is relatively loose in the peripheral circuit region P than in the region M and accordingly, the peripheral circuit region P has variations in the pattern. As a result, multi exposure is sometimes carried out, that is, optical conditions of the exposure process are sometimes set so as to be suitable for each of the regions M and P. In such multi exposure, bad influences are produced in exposure boundary between the regions M and P. A resist-removed region N and boundary K are provided between the regions M and P so that mutual influences are reduced between the regions M and P during exposure as much as possible.

A plurality of mask patterns are prepared in the case of multi exposure. FIG. 1B illustrates an example of photomask pattern in the case where the memory cell region M is exposed to light. FIG. 1C illustrates an example of photomask pattern in the case where a peripheral circuit region is exposed to light. Each of two shielding parts S is provided for shielding one of the regions M and P while the other is exposed to light in the case where the regions M and P are separately exposed to light using the mask patterns as shown in FIGS. 1B and 1C.

However, when the mask pattern to be prepared has an extremely larger light-shielding part S as compared with the memory cell region M, the above-mentioned problem cannot be overcome only by the techniques disclosed in the aforementioned references. In view of the condition, the inventors focused their attention on dimensions of the memory cell array and the distance from an end of the memory cell array to the shielding region. Amounts of variations in the width and length (lengthwise dimension) are previously obtained according to the dimensions and distance. A correction process is carried out according to the obtained amounts, whereupon the variations in the linewidth in the memory cell region M can be suppressed.

### CONCRETE EXAMPLE

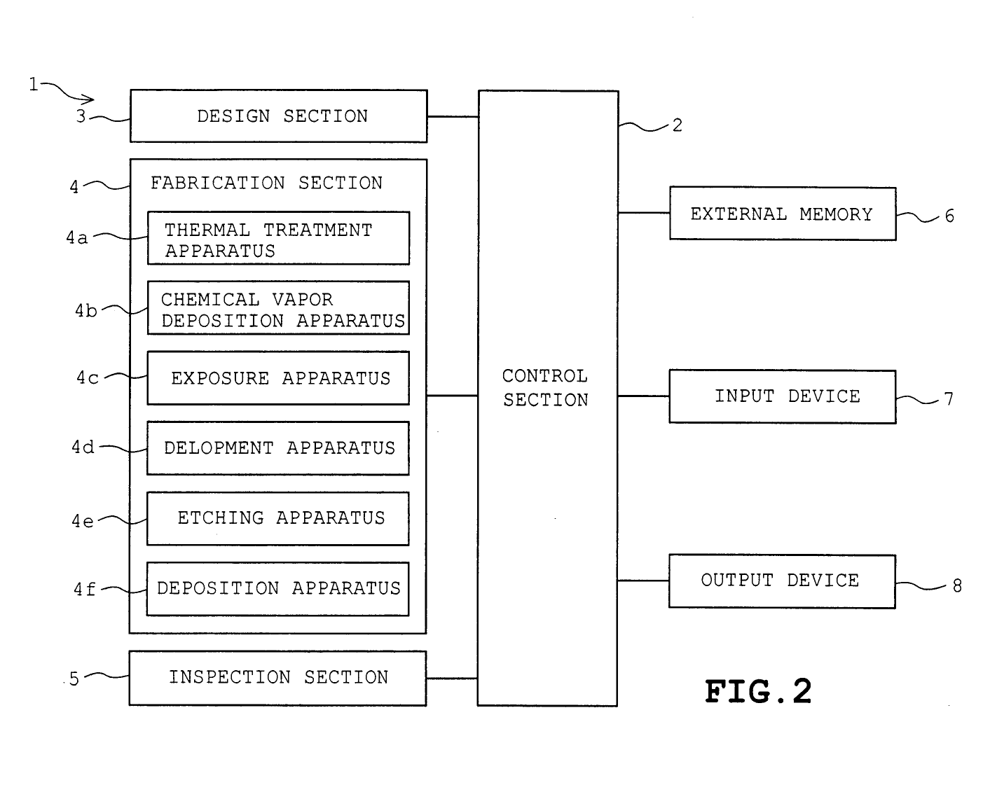

A concrete example will now be described with reference to FIG. 2 which is a block diagram schematically showing an electrical arrangement of a semiconductor design and fabrication management system. Referring to FIG. 2, the semiconductor design and fabrication management system 1 serving as a designing apparatus comprises a control section (correcting section) 2, a design section 3, a fabrication section 4, an inspection section 5, an external memory 6, an input device 7 and an output device 8.

The design section 3 comprises a computer to which a storage medium capable of storing a program is connectable, for example. More specifically, the design section 3 is provided with a computer assisted design (CAD) system which carries out design of a circuit and layout of a semiconductor device, layout of a photomask and the like, and fabrication of the photomask and the like. The design section 3 is further provided with a pattern generator (PG) and database of various design information, neither of which is shown. When details of the circuit and layout of the semiconductor device and a mask pattern of the circuit are designed by the CAD system, data of the circuit, layout, mask pattern and the like are stored on a design information database (not shown). Furthermore, various correction data for an exposure apparatus 4c are stored on the design information database. A photomask for fabrication of a semiconductor device is produced based on the design information stored on the design information database.

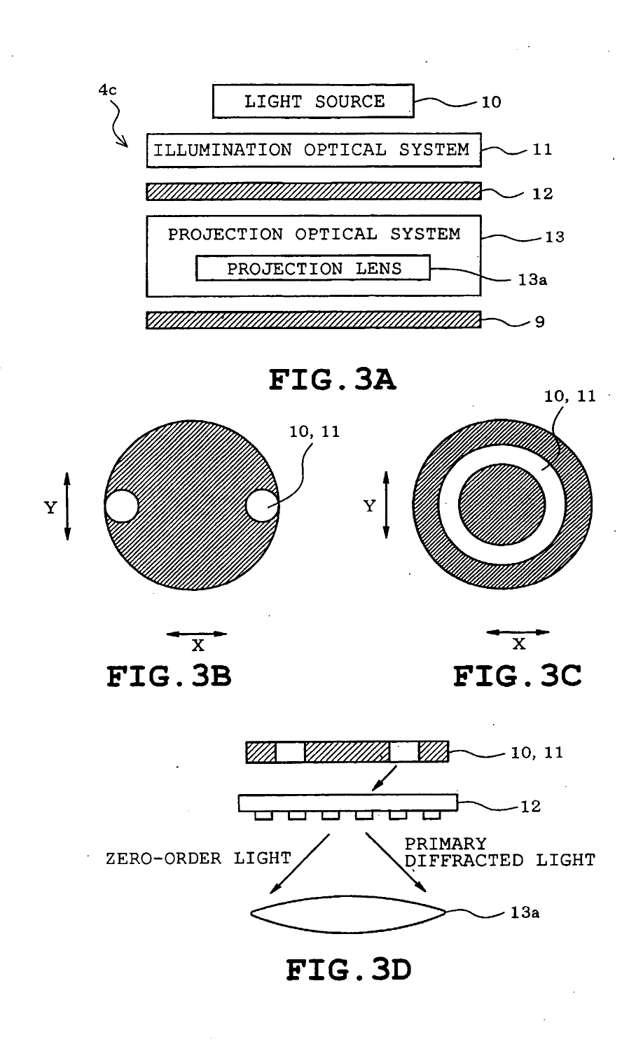

The inspection section 5 comprises a computer provided with a storage medium which is capable of storing a program. More specifically, the inspection section 5 includes various inspection devices which carry out measurement and inspection with respect to the semiconductor substrate 9 (see FIG. 3A) processed in the fabrication section 4. For example, the inspection devices include an optical microscope for surface observation, a transmission electron microscope (TEM) for structural analysis, a scanning electron microscope (SEM) for surface observation and structural analysis, and the like.

The external memory 6 is capable of temporarily storing various information such as correction data delivered from the control section 2. The input device 7 includes various input units such as a keyboard, mouse, digitizer, etc. When information is delivered into the input device 7, an operation input signal is supplied into the control section 2. The output device 8 is composed of various visually recognizing units such as a liquid crystal display, light-emitting diode, electroluminescence (EL). The output device 8 is arranged so as to display various information delivered from the control section 2.

The control section 2 comprises a computer provided with a storage medium capable of storing various programs such as a control program, correction program and the like. The control section 2 executes various correcting processes based on operation instruction signals supplied from the input device 7. The control section 2 is arranged so as to carry out a correction process on influences of exposure process for the semiconductor substrate (coverage dependency of mask pattern), PEB, development process and dimensional variations of mask pattern.

FIG. 3A schematically exemplifies an arrangement of the exposure apparatus. An ArF excimer laser exposure apparatus is used as the exposure apparatus 4c. The exposure apparatus 4c comprises a light source 10, illumination optical system 11 which transmits exposed light produced from the light source 10, a photomask 12 on which the exposure light having transmitted the illumination optical system 11 falls, a projection optical system 13 on which the exposure light having transmitted the illumination optical system 11 falls, so that the semiconductor substrate 9 is irradiated with the light. The light source 10 comprises an ArF excimer laser with the wavelength of 193 nm. In execution of multiple exposure to the memory cell region M and peripheral circuit region P, the illumination conditions of the light source 10 and illumination optical system 11 are changed so that exposure light is emitted through the photomask 12. FIG. 3B shows illumination conditions in the case where a memory cell region is exposed to light.

When the memory cell region M is exposed to light, a number of parallel line-and-space patterns (L/S patterns, flocculent patterns) extending in a predetermined direction are often formed on the semiconductor substrate 9 as a resist pattern. When the lengthwise direction with respect to the L/S patterns is referred to as “Y direction” (vertical direction), the light source 10 and illumination optical system 11 are arranged so that illumination light is emitted onto the photomask 12 from two locations which are located vertically centrally and spaced from each other in the X direction (horizontal direction) perpendicular to the Y direction. This illumination condition is referred to as “dipole illumination condition.” When the dipole illumination condition is applied to the example, the illumination condition is particularly suitable for the case where the L/S pattern is exposed to light. The Y direction (s-polarized) is set as the polarization direction of light for the purpose of improvement in the contrast.

FIG. 3C shows illumination conditions in the case where the peripheral circuit region is exposed to light. The peripheral circuit region P is provided around the memory cell region M. Since the memory cell region M has a large variation, the illumination condition needs to be set so that the peripheral circuit region P is uniformly irradiated with light. In the example, annular illumination is applied as the illumination light emitted from the light source 10 and illumination optical system 11 so that exposure is suitably omni directional. The polarization condition is set to “no polarization.”

Returning to FIG. 3A, the photomask 12 is a semi-transmission phase shift film is applied as the photomask 12 to a region where a pattern is actually formed. More specifically, in a normal photomask using a light-shielding film such as a Cr film as a pattern forming film, light is spread to a dark pattern portion which should not normally be exposed to light. Spread light is intensified by other spread light such that even the dark pattern portion is exposed. However, application of the semi-transmission phase shift film shifts by 180° the phase of the light having passed through the phase shift film. Consequently, the light spread to the dark pattern portion is denied by other spread light such that the dark pattern portion is not exposed to light. Accordingly, the phase shift mask can be applied to fabrication of a refined semiconductor device as compared with the normal photomask.

The projection optical system 13 comprises a projection lens 13a and an aperture stop (not shown). Illumination light having passed through the illumination optical system 11 further passes via the photomask 12 through projection optical system 13 to be reduced and projected onto the semiconductor substrate 9 as exposed light.

FIG. 3D schematically shows a light path of light emitted under the dipole illumination condition in the exposure of the memory cell region to light. Light emitted under the dipole illumination condition is grazing incident relative to the photomask 12. The grazing incident illumination light is emerged through a pattern formed on the photomask 12. Zero-order light and primary diffracted light are obtained by the photomask. The zero-order light and primary diffracted light are set so as to be incident on one end side and the other end side of outermost periphery of the projection lens 13a constituting the projection optical system 13 respectively. This grazing incidence is carried out in order that the resolution on the edge of the number of apertures of the exposure apparatus 4c specialized in fine pattern.

Conditions and results of an experiment will now be described. The number of apertures (NA) of the projection optical system 13 in the exposure of the memory cell region to light is set to 0.92 and the number of apertures (NA) of the illumination optical system 11 is set to 0.92×0.97. In this case, the value of σ is set to 0.97 when the σ value (coherence factor) is defined as:
σ=number of apertures of illumination optical system/number of apertures of projection optical system. (1)
Furthermore, an inner a of the annular illumination in the exposure of the peripheral circuit region P to light is set to 0.75 and an outer σ of the annular illumination is set to 0.5.

The inventors applied an antireflection film to the semiconductor substrate 9 and further a positive chemical amplification resist to the antireflection film in the experiment. These conditions are optimum exposure conditions (the number of apertures (NA), illumination shape, resist conditions, etc.) in the case where the memory cell region M and peripheral circuit region P are exposed to light.

FIG. 1A shows a composition example of a necessary resist pattern. A pattern M1 corresponding to the memory cell region M is provided in the center of a whole pattern region Z. A resist-removed portion N is provided around an outer periphery of the pattern M1. The boundary K of the resist pattern is provided around the outer periphery of the resist-removed portion N. A pattern P1 corresponding to the peripheral circuit region P is provided at the outer peripheral side of the boundary K of the resist pattern. The experiment was conducted with use of the aforesaid pattern. The resist-removed portion N serves as a margin region of the pattern. The boundary K serves as a boundary between the memory cell region M and the peripheral circuit region P in the double exposure.

The pattern M1 corresponding to the memory cell region M includes a number of L/S patterns extending in the Y direction so that the patterns are parallel with each other or one another. Accordingly, as shown in FIG. 1D, the mask pattern M1 includes transmission regions Ta and semi-transmission regions Tb which both extend in the Y direction. The transmission regions Ta and semi-transmission regions Tb are disposed alternately in the X direction and serve as exposure light transmission regions.

The pattern P1 corresponding to the peripheral circuit region P constitutes elements such as transistors for driving memory cells of the memory cell region M. The pattern P1 of the photomask 12 is composed of a combination of the transmission region Ta and the semi-transmission region Tb. In this case, the transmission region Ta of the pattern P1 of the photomask 12 has a larger whole area than the semi-transmission region Tb. A light-shielding part S is composed so as to cover both regions K and P1. The memory cell region M is exposed to light using the pattern M1 as shown in FIG. 1B. Furthermore, the light-shielding part S is also composed so as to cover the regions M1, N and K. The peripheral circuit region P is exposed to light using the pattern P1. Thus, a double exposure process is applied.

FIG. 1D shows in an enlarged scale the photomask 12 corresponding to an end of the pattern M1. The transmission region Ta and the semi-transmission region Tb are provided substantially in the center of the pattern M1 corresponding to the memory cell region M as shown in FIG. 1D. Each of the regions Ta and Tb has a length in the Y direction. Both regions Ta and Tb are disposed alternately in the X direction. Consequently, the transmission and semi-transmission regions Ta and Tb constitute the L/S patterns. A predetermined range of the transmission region Ta around the L/S patterns serves as a margin.

Light with a predetermined wavelength (λ=193 nm, for example) is allowed to pass through the transmission region Ta. The semi-transmission region Tb has an optical characteristic that the transmission factor is about single percent (6%, for example) at a predetermined wavelength and that the semi-transmission region Tb has a 180-degree phase shift relative to the transmission region Ta. In the pattern M1 in the exposure of the memory cell region M, the semi-transmission region Tb is composed as a pattern long in a predetermined direction (Y direction). The light-shielding part S designates a region where light with the predetermined wavelength is shielded.

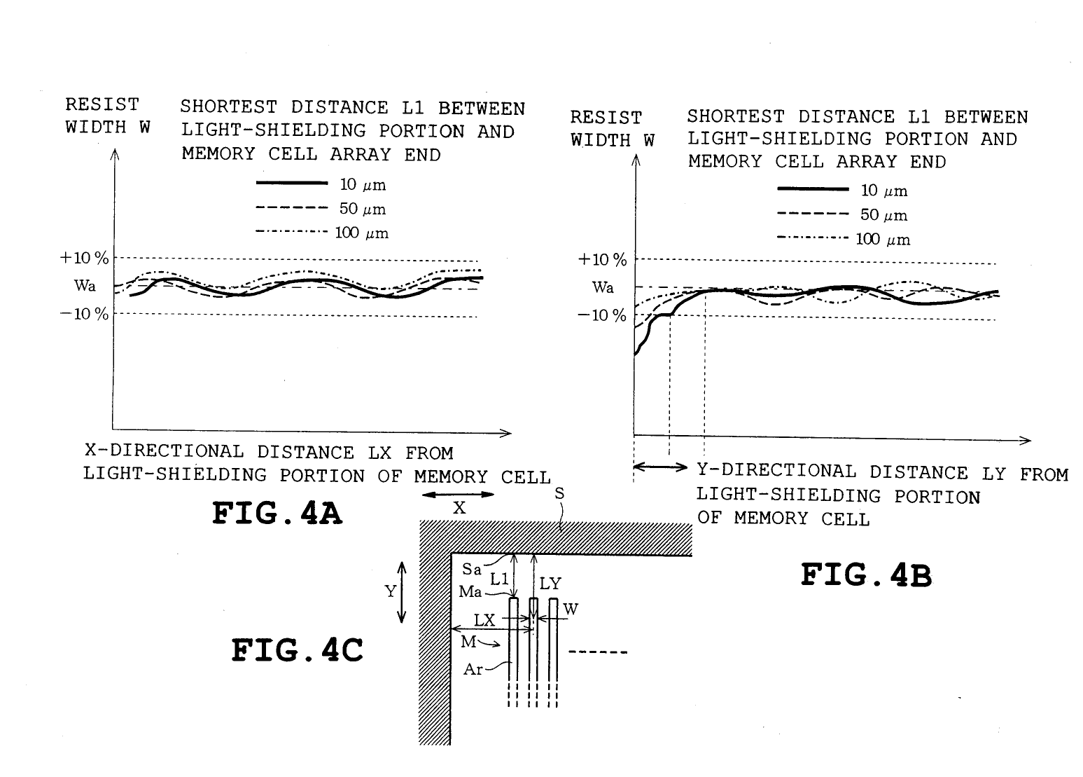

The inventors made a mask in full consideration of influences of process proximity effect resulting from double exposure with the use of two photomasks 12 by means of simulation. Regarding the end of the memory cell region M (several μm regional width d as shown in FIG. 1B), the inventors carried out the conventional correction and furthermore designed the photomask 12 in consideration of the conventional correction techniques of the conventional examples (JP-2005-203637A and JP-2005-338267A) and correction amounts of flare amounts under exposure conditions of respective regions M and P. More specifically, when the dimensions of the mask pattern M1 of the memory cell region M are to be corrected, correction is carried out in consideration of flare in the case where the pattern P1 of the peripheral circuit region P is exposed. Similarly, regarding dimensional correction of mask pattern P1 of the peripheral circuit region P, too, correction is carried out in consideration of the influences of flare in the case where the pattern M1 of the memory cell region M is exposed to light. FIGS. 4A and 4B show the results of measurement of the widths of the resists formed by the exposure process carried out under these conditions.

The width W of resist pattern varies depending upon the shortest distance (L1) between the semi-transmission region Tb and the light-shielding part S when a target width of the resist pattern formed on the semiconductor substrate 9 is designated by symbol “Wa” as shown in FIGS. 4A and 4B. The aforesaid shortest distance L1 corresponds to the shortest distance from the Y-directional end Ma of the memory cell region M to an inner edge Sa of the light-shielding part S as shown in FIG. 4C. Particularly regarding the X direction, the width W of the resist pattern spaced from the light-shielding part S in the X direction by distance LX does not almost vary thereby to stay within an allowable range (±10%, for example) as the result of the correction process taking account of the conventional process proximity process (PPE) and the correction process taking account of the coverage dependency. However, the resist width W is extremely smaller as compared with the target width Wa of the memory cell region M as the Y-directional distance LY from the end Sa of the light-shielding part S is short. It has been confirmed that these influences result from a cause which cannot be eliminated by the conventional correction process. Furthermore, the width W of the resist pattern tends to be increased beyond the allowable range (±10%, for example) in extreme cases.

The aforesaid cause can be considered as follows. When the memory cell region M is exposed to light using the pattern M1, the emitted light is extremely grazing incident relative to the photomask 12. Furthermore, since the Y direction is set as the polarization direction of light, a portion of the Y-directional memory cell region M near to the end Ma is influenced by complex multiple reflection etc. Consequently, the transcription property cannot be determined accurately by the conventional prediction method.

The inventors found that variations in the entire line width of the memory cell region M was suppressed by previously obtaining X-directional and Y-directional amounts of dimensional variations according to the distance between the end Ma of the memory cell region M (memory cell array Ar) and the inner edge Sa of the light-shielding part S and by carrying out correction for each of the X and Y directions on the basis of the obtained result.

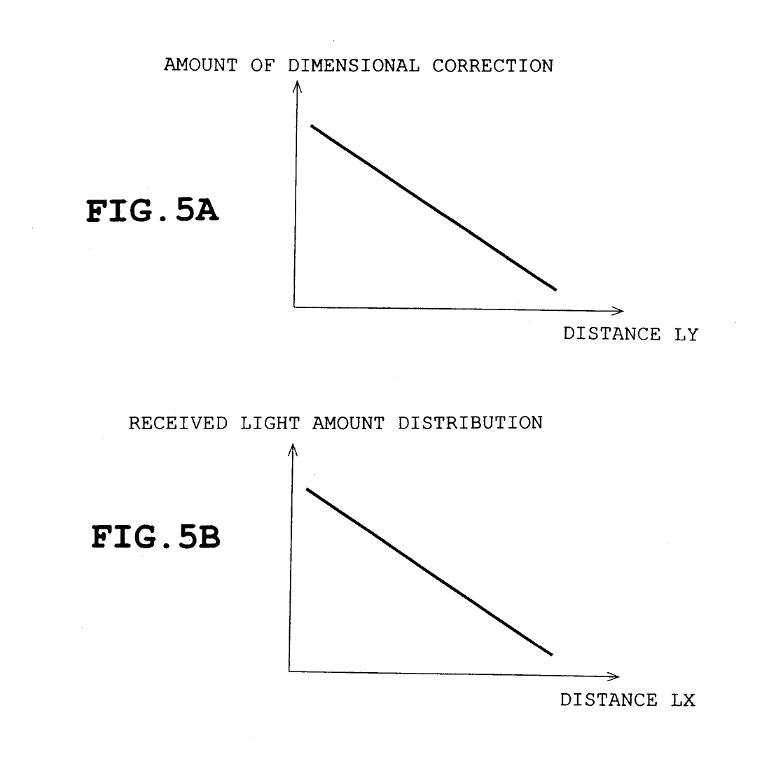

FIG. 5A schematically shows distance dependency of an amount of dimensional correction used in the correction process. FIG. 5B schematically shows distance dependency of the distribution of an amount of light received. An amount of dimensional correction is linearly decreased with increase in the distance between the end Ma of the memory cell region M (memory cell array Ar) and the inner edge Sa of the light-shielding part S as shown in FIG. 5A. The amount of dimensional correction is determined according to an amount of variation of longitudinal resist width W as shown in FIG. 4B. The distribution of received light amount is linearly decreased with increase in the distance between the end Ma of the memory cell region M (memory cell array Ar) and the inner edge Sa of the light-shielding part S as shown in FIG. 5B. The distribution of received light amount is obtained according to the Y-directional distance from the inner edge Sa of the light-shielding part S of the memory cell M as shown by the axis of abscissas in FIG. 4B. The distribution of received light amount is used to correct the mask dimensions with additions of the amount of light received in OPC.

Correction data thus obtained is stored on a storage medium such as database. The control section 2 carries out correction using the correction data, whereupon the dimensional variation which could not be corrected by the conventional method can be suppressed. As a result, the dimensional variation can be suppressed omni directionally with respect to the memory cell array Ar of the memory cell region M and accordingly, the multi exposure photomask 12 with high yield and high quality can be provided. More specifically, when the resist pattern width is designed by the design section 3 and thereafter the correction is carried out by the control section 2, the correction is carried out so that the width W of the resist pattern of the semi-transmission region Tb is rendered larger as the resist pattern of the semi-transmission Tb comes close to the inner edge Sa of the light-shielding part S. In contrast, the correction is carried out so that the width W of the resist pattern of the semi-transmission region Tb is rendered smaller as the resist pattern of the semi-transmission Tb goes away from the inner edge Sa of the light-shielding part S.

Furthermore, the correction is carried out so that an X-directional amount of dimensional correct is rendered larger as the resist pattern of the semi-transmission Tb comes close to the inner edge Sa of the light-shielding part S. On the other hand, the correction is carried out so that an X-directional amount of dimensional correct is rendered smaller as the resist pattern of the semi-transmission Tb goes away from the inner edge Sa of the light-shielding part S. As the result of the above-described correction carried out by the control section 2, the X-directional width W of the resist can be adjusted to the target dimension Wa. Consequently, a desired fine pattern with less dimensional variation can be formed even when the resist is applied to the semiconductor substrate 9 and then patterned.

The conventional development is directed to reduction in the distance between the peripheral circuit region P and the memory cell array Ar of the memory cell region M. This results from requirement for reduction in the chip area and requirement in a process of dummy pattern provided between the peripheral circuit region P and the memory cell array Ar or a guard ring region. However, the experimental result shows that the resist pattern width tends to come closer to the target width as the shortest distance from the end Ma of the memory cell region M (memory cell array Ar) to the light-shielding part S is increased. Accordingly, in order that the width of the resist may strictly be adjusted, the distance between the peripheral circuit region P and the memory cell array Ar of the memory cell region M is increased.

According to the foregoing embodiment, the semi-transmission region Tb, the transmission region Ta and the light-shielding part S larger than the memory cell region M are provided sequentially outward in this order so as to extend in the Y direction (particularly, the lengthwise direction of the L/S pattern) from the end Ma of the memory cell region M located in the center of the whole region Z of the pattern. The X-directional width of the semi-transmission region Tb is set so as to be larger as the distance from the semi-transmission region Tb to the light-shielding part S is rendered shorter. On the other hand, the X-directional width of the semi-transmission region Tb is set so as to be smaller as the distance from the semi-transmission region Tb to the light-shielding part S is rendered longer. These setting manners of the X-directional width of the semi-transmission region Tb can suppress the variations in the width of the pattern resulting from the cause which could not be overcome by the conventional correction process with the coverage dependency etc. Consequently, a desired fine pattern with less dimensional variation can be formed.

Furthermore, a correction amount of the X-directional dimension of the semi-transmission region Tb, for example, is set to be larger as the distance from the semi-transmission region Tb to the light-shielding part S is short. A correction amount of the X-directional dimension of the semi-transmission region Tb, for example, is set to be smaller as the distance from the semi-transmission region Tb to the inner edge Sa of the light-shielding part S is long. These setting manners of the X-directional width of the semi-transmission region Tb can suppress the variations in the width of the pattern resulting from the cause which could not be overcome by the conventional correction process with the coverage dependency etc. Consequently, a desired fine pattern with less dimensional variation can be formed.

Furthermore, the dipole illuminations are applied to the light source 10 and illumination optical system 11. The dipole illumination systems are disposed so as to be located in the center in the Y direction spaced away from each other in the X direction. In this case, since the photomask 12 is irradiated with light so that X-directional and Y-directional pattern resolutions differ from each other, this irradiation manner is suitable for the case where a number of elongate patterns are provided in a predetermined direction as in the L/S pattern.

Since Y-directionally polarized light is incident on the photomask 12, the contrast can be improved when the L/S pattern is formed so as to be longer in the Y direction than in the X direction. Furthermore, the photomask 12 is used to expose the memory cell region M to light in the foregoing embodiment. The photomask 12 can be applied to a memory cell region M of a flash memory which has recently necessitated refinement. Additionally, the foregoing embodiment can be applied to multiple exposure, whereupon a desired pattern with less dimensional variation can be formed after multiple exposure.

The invention should not be limited by the foregoing description of the embodiment. The embodiment may be modified or expanded as follows. Although the invention is applied to the positive photoresist 12 in the foregoing embodiment, the invention may also be applied to a negative photomask. In this case, a transmission region Ta is applied as the semi-transmission region and a semi-transmission region Tb is applied to the transmission region. Consequently, the same effect can be achieved from the modified form as that achieved form the foregoing embodiment.

The invention is applied to the double exposure in the foregoing embodiment. However, the invention may be applied to multiple exposure or a process in which only the memory cell region M is exposed to light. The invention may further be applied to fine patterns of other types of semiconductor devices than the memory cell region M of the flash memory.

A relative distance is defined between the pattern M1 of the memory cell region M and the light-shielding part S in the foregoing embodiment. The tendency of the direction of correction does not change even depending upon the size of the region of the pattern M1 of the memory cell region M. Accordingly, the invention may be applied to any scale of pattern M1.

The resist-removed portion N is provided with a transmission region Ta serving as a margin region in the foregoing embodiment. However, the resist-removed portion N may be provided with the semi-transmission region Tb serving as a margin region, instead. Additionally, although the dipole illumination systems as shown in FIG. 2A are described as the illumination condition in the foregoing embodiment, the illumination condition may include centrally provided illumination in addition to the dipole illumination.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A photomask designing apparatus designing a photomask which is provided with a light transmission region through which exposure light with a predetermined wavelength transmits, a semi-transmission region having an optical characteristic of 180-degree phase shift and a light shielding region shielding exposure light, wherein the semi-transmission region has a width set so as to be larger as a distance from the semi-transmission region to the light shielding region becomes short with respect to a region in which the semi-transmission region, the light transmission region and the light shielding region are sequentially provided outward from an exposure light passing region side, and the width of the semi-transmission region is set so as to be smaller as the distance becomes long.

2. The photomask designing apparatus according to claim 1, wherein the photomask is formed with a line and space pattern (L/S pattern) and has a lengthwise direction in which the semi-transmission region, the light transmission region and the light shielding region are sequentially provided outward from the exposure light passing region side, and the semi-transmission region has a width having a direction perpendicular to the lengthwise direction of the L/S pattern.

3. A photomask fabricated with the use of a photomask designing apparatus designing a photomask which is provided with a light transmission region through which exposure light with a predetermined wavelength transmits, a semi-transmission region having an optical characteristic of 180-degree phase shift and a light shielding region, wherein the semi-transmission region has a width set so as to be larger as a distance from the semi-transmission region to the light shielding region becomes short with respect to a region in which the semi-transmission region, the light transmission region and the light shielding region are sequentially provided outward from an exposure light passing region side, and the width of the semi-transmission region is set so as to be smaller as the distance becomes long.

4. The photomask according to claim 3, wherein the photomask is formed with a line and space pattern (L/S pattern) and has a lengthwise direction in which the semi-transmission region, the light transmission and the light shielding region are sequentially provided outward from the exposure light passing region side, and the semi-transmission region has a width having a direction perpendicular to the lengthwise direction of the L/S pattern.

5. A photomask designing apparatus designing a photomask which is provided with a light transmission region through which exposure light with a predetermined wavelength transmits, a semi-transmission region having an optical characteristic of 180-degree phase shift and a light shielding region, wherein the light transmission region has a width set so as to be larger as a distance from the light transmission region to the light shielding region becomes short with respect to a region in which the light transmission region, the semi-transmission region and the light shielding region are sequentially provided outward from an exposure light passing region side, and the width of the light transmission region is set so as to be smaller as the distance becomes long.

6. The photomask designing apparatus according to claim 5, wherein the photomask is formed with a line and space pattern (L/S pattern) and has a lengthwise direction in which the semi-transmission region, the light transmission region and the light shielding region are sequentially provided outward from the exposure light passing region side, and the light transmission region has a width having a direction perpendicular to the lengthwise direction of the L/S pattern.

7. A photomask fabricated with the use of a photomask designing apparatus designing a photomask which is provided with a light transmission region through which exposure light with a predetermined wavelength transmits, a semi-transmission region having an optical characteristic of 180-degree phase shift and a light shielding region, wherein the light transmission region has a width set so as to be larger as a distance from the light transmission region to the light shielding region becomes short with respect to a region in which the light transmission region, the semi-transmission region and the light shielding region are sequentially provided outward from an exposure light passing region side, and the width of the light transmission region is set so as to be smaller as the distance becomes long.

8. The photomask according to claim 7, wherein the photomask is formed with a line and space pattern (L/S pattern) and has a lengthwise direction in which the semi-transmission region, the light transmission region and the light shielding region are sequentially provided outward from the exposure light passing region side, and the light transmission region has a width having a direction perpendicular to the lengthwise direction of the L/S pattern.

9. A photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising:
setting the width of the semi-transmission region so that the width of the semi-transmission region is larger as a distance from the semi-transmission region to the light shielding region becomes short with respect to a region in which the semi-transmission region, the light transmission region and the light shielding region are sequentially provided outward from an exposure light passing region side; and
setting the width of the semi-transmission region so that the width of the semi-transmission region is smaller as the distance becomes long.

10. The method according to claim 9, wherein the photomask is formed with a line and space pattern (L/S pattern) and has a lengthwise direction in which the semi-transmission region, the light transmission region and the light shielding region are sequentially provided outward from the exposure light passing region side, and the semi-transmission region has a width having a direction perpendicular to the lengthwise direction of the L/S pattern.

11. A photomask designing program which is computer readable and accomplishes a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising:
setting the width of the semi-transmission region so that the width of the semi-transmission region is larger as a distance from the semi-transmission region to the light shielding region becomes short with respect to a region in which the semi-transmission region, the light transmission region and the light shielding region are sequentially provided outward from an exposure light passing region side; and
setting the width of the semi-transmission region so that the width of the semi-transmission region is smaller as the distance becomes long.

12. The photomask designing program according to claim 11, wherein the photomask is formed with a line and space pattern (L/S pattern) and has a lengthwise direction in which the semi-transmission region, the light transmission region and the light shielding region are sequentially provided outward from the exposure light passing region side, and the semi-transmission region has a width having a direction perpendicular to the lengthwise direction of the L/S pattern.

13. A storage medium on which a photomask designing program is stored, the photomask designing program which is computer readable and accomplishes a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising:
setting the width of the semi-transmission region so that the width of the semi-transmission region is larger as a distance from the semi-transmission region to the light shielding region becomes short with respect to a region in which the semi-transmission region, the light transmission region and the light shielding region are sequentially provided outward from an exposure light passing region side; and
setting the width of the semi-transmission region so that the width of the semi-transmission region is smaller as the distance becomes long.

14. The storage medium according to claim 13, wherein the photomask is formed with a line and space pattern (L/S pattern) and has a lengthwise direction in which the semi-transmission region, the light transmission region and the light shielding region are sequentially provided outward from the exposure light passing region side, and the semi-transmission region has a width having a direction perpendicular to the lengthwise direction of the L/S pattern.

15. A photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising:
setting the width of the semi-transmission region so that the width of the semi-transmission region is larger as a distance from the light transmission region to the light shielding region becomes short with respect to a region in which the light transmission region, the semi-transmission region and the light shielding region are sequentially provided outward from an exposure light passing region side; and
setting the width of the semi-transmission region so that the width of the light transmission region is smaller as the distance becomes long.

16. The method according to claim 15, wherein the photomask is formed with a line and space pattern (L/S pattern) and has a lengthwise direction in which the semi-transmission region, the light transmission region and the light shielding region are sequentially provided outward from the exposure light passing region side, and the light transmission region has a width having a direction perpendicular to the lengthwise direction of the L/S pattern.

17. A photomask designing program for accomplishing a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising:
setting the width of the semi-transmission region so that the width of the semi-transmission region is larger as a distance from the light transmission region to the light shielding region becomes short with respect to a region in which the light transmission region, the semi-transmission region and the light shielding region are sequentially provided outward from an exposure light passing region side; and
setting the width of the semi-transmission region so that the width of the light transmission region is smaller as the distance becomes long.

18. A storage medium on which a photomask designing program is stored, the photomask designing program being computer readable and accomplishing a photomask designing method of designing a photomask which is provided with a light transmission region through which exposure light with a predetermined wavelength transmits, a semi-transmission region having an optical characteristic of 180-degree phase shift and a light shielding region shielding exposure light, the semi-transmission region having a width, the method comprising:
setting the width of the semi-transmission region so that the width of the semi-transmission region is larger as a distance from the semi-transmission region to the light shielding region becomes short with respect to a region in which the semi-transmission region, the light transmission region and the light shielding region are sequentially provided outward from an exposure light passing region side; and
setting the width of the semi-transmission region so that the width of the semi-transmission region is smaller as the distance becomes long.
